(19) United States
(12) Patent Application Publication
(10) Pub. No.: US 2006/0292883 A1
(43) Pub. Date: Dec. 28, 2006

(54) ETCHING OF SILICON NITRIDE WITH IMPROVED NITRIDE-TO-OXIDE SELECTIVITY UTILIZING HALOGEN BROMIDE/CHLORINE PLASMA

(76) Inventor: Chang-Hu Tsai, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/160,521

(22) Filed: Jun. 28, 2005

(51) Int. Cl. H01L 21/302

(52) U.S. Cl. 438/710; 438/689

(57) ABSTRACT

A method of manufacturing a semiconductor device is disclosed. A gate is formed on a semiconductor substrate. A gate oxide is formed between the gate and the semiconductor substrate. A silicon oxide liner layer is deposited on the gate and on the semiconductor substrate. A silicon nitride layer is then deposited on the silicon oxide liner layer. The silicon nitride layer is anisotropically etched by employing plasma created by using plasma source gas containing hydrogen bromide and chlorine thereby forming spacer on sidewalls of the gate. The hydrogen bromide plasma is produced at a temperature of about 50-150° C., a pressure of 5-200 mTorr, a source power of no less than 800 Watts, and a bias power of about 100-200 Watts.

### BACKGROUND OF THE INVENTION

1. Field of the Invention

The present invention relates generally to a method of making a semiconductor device and, more particularly, to a method of etching silicon nitride with improved nitride-to-oxide selectivity utilizing hydrogen bromide/chlorine (HBr/Cl₂) plasma.

2. Description of the Prior Art

Dimensional control in etching small features, necessary for advanced micromachining, is an important topic in silicon technology. To etch these structures, dry plasma-assisted etching is increasingly used. In the fabrication of semiconductor devices, it is often desirable to dry etch silicon nitride with high selectivity relative to silicon oxide.

FIG. 1 and FIG. 2 are schematic diagrams showing the method of making silicon nitride spacer on gate sidewalls according to the prior art. As shown in FIG. 1, a gate 12 is formed on the main surface of the semiconductor substrate 10. Between the gate 12 and the semiconductor substrate 10 is disposed a gate oxide layer 14. Using conventional chemical vapor deposition (CVD) methods, a silicon oxide layer 16 and a silicon nitride layer 18 are sequentially deposited onto the top surface and sidewalls of the gate 12 and onto the semiconductor substrate 10. Typically, the thickness of the silicon oxide layer 16, which functions as a liner, is about 80-200 angstroms.

As shown in FIG. 2, after the deposition of the silicon nitride layer 18, the semiconductor substrate 10 is subjected to a dry etching process. The substrate or wafer is placed in an airtight vacuum chamber of a conventional etcher tool. In the vacuum chamber, the pressure is maintained at about 300-400 mTorr. Plasma source gas typically including carbon fluoride, such as CF₄ or CHF₃, and oxygen are introduced into the vacuum chamber. The carbon fluoride plasma is then ignited by providing the plasma source gas with a source power of about 100-200 Watt. The silicon nitride layer 18 is exposed to the carbon fluoride plasma and anisotropically etched to form nitride spacers 20.

The above-described prior art method has several disadvantages, one of which is low nitride-to-oxide selectivity (typically less than 20). The nitride-to-oxide selectivity is defined as the ratio of etching rate of the silicon nitride layer to the etching rate of silicon oxide. Low nitride-to-oxide selectivity leads to overetching of semiconductor substrate 10 (as indicated by dash line).

### SUMMARY OF THE INVENTION

It is the primary object of the present invention to provide a method of etching silicon nitride with improved nitride-to-oxide selectivity.

According to the claimed invention, a method of manufacturing a semiconductor device is disclosed. A gate is formed on a semiconductor substrate. A gate oxide is formed between the gate and the semiconductor substrate. A silicon oxide liner layer is deposited on the gate and on the semiconductor substrate. A silicon nitride layer is then deposited on the silicon oxide liner layer. The silicon nitride layer is anisotropically etched by employing plasma created by using plasma source gas containing hydrogen bromide and chlorine thereby forming spacer on sidewalls of the gate. The hydrogen bromide plasma is produced at a temperature of about 50-150° C., a pressure of 5-200 mTorr, a source power of no less than 800 Watts, and a bias power of about 100-200 Watts.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams showing the method of making silicon nitride spacer on gate sidewalls according to the prior art.

FIG. 3 and FIG. 4 are schematic, cross-sectional diagrams illustrating the etching of silicon nitride spacers utilizing HBr/Cl₂ plasma in accordance with the first preferred embodiment of this invention.

FIG. 5 and FIG. 6 are schematic, cross-sectional diagrams illustrating the etching of ONO spacers utilizing HBr/Cl₂ plasma in accordance with the second preferred embodiment of this invention.

FIGS. 7-10 are schematic, cross-sectional diagrams showing the exemplary process of making contact holes by employing the present invention HBr/Cl₂ plasma etching.

FIGS. 11-15 are schematic, cross-sectional diagrams showing the exemplary process of making a dual damascene structure by employing the present invention HBr/Cl₂ plasma etching.

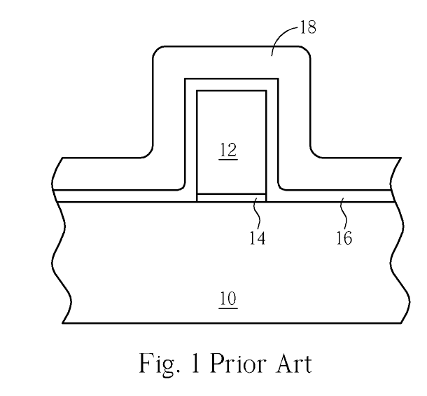

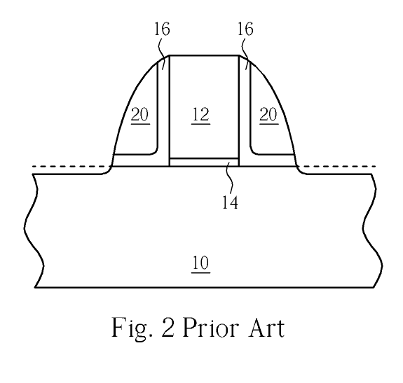

### DETAILED DESCRIPTION

The present invention pertains to a semiconductor etching process utilizing hydrogen bromide and chlorine (HBr/Cl₂) as plasma source gases for improving nitride-to-oxide selectivity. Exemplary embodiments from different aspects of this invention are proposed with reference to the accompanying figures. These exemplary embodiments can be performed in a Lam 2300 series etcher tool available from Lam Research Corp. or in other similar etcher tools that are capable of providing source power (i.e., top power) and bias power (i.e., bottom power). Hereinafter, the nitride-to-oxide selectivity is defined as the ratio of etching rate of silicon nitride to the etching rate of silicon oxide.

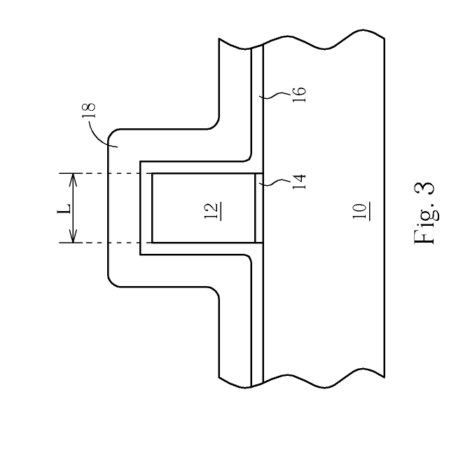

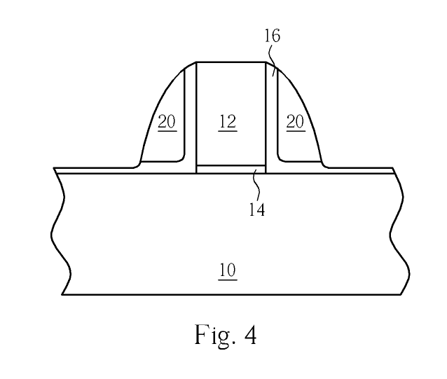

Please refer to FIG. 3 and FIG. 4. FIG. 3 and FIG. 4 are schematic, cross-sectional diagrams illustrating the etching of silicon nitride spacers utilizing HBr/Cl₂ plasma in accordance with the first preferred embodiment of this invention. As shown in FIG. 3, a gate 12 having a gate channel length L of about 40-100 nm is formed on the main surface of the semiconductor substrate 10. The formed gate 12 may comprise polysilicon and silicide. A 5-30 angstrom thick gate oxide layer 14 is disposed between the gate 12 and the substrate 10.

Subsequently, conventional chemical vapor deposition (CVD) processes are performed to deposit a silicon oxide layer 16 and a silicon nitride layer 18 onto the gate 12 and onto the semiconductor substrate 10. The silicon oxide layer 16 covers the top surface and sidewalls of the gate 12. According to this preferred embodiment, the thickness of the silicon oxide layer 16 is about 80-200 angstroms.

As shown in FIG. 4, after the CVD deposition of the silicon nitride layer 18, the substrate 10 is placed in an airtight vacuum chamber (not shown) of an etcher tool such as Lam 2300 series etcher tool available from Lam Research Corp. under a chamber pressure maintained at 5-200 mTorr and a chamber temperature of about 70° C. Plasma source gases including hydrogen bromide, chlorine, and, optionally, oxygen are introduced into the vacuum chamber. The HBr/Cl₂ plasma is then ignited by providing the plasma source gas with a source power of no less than 800 Watts and a bias power of about 100-200 Watts. The silicon nitride layer 18 is exposed to the HBr/Cl₂ plasma and anisotropically etched to form nitride spacers 20.

The present invention HBr/Cl₂ plasma etching is preferably carried out in a higher temperature of about 20-150° C., more preferably, 50-100° C., most preferably 70° C. The temperature under which the HBr/Cl₂ plasma etching is carried out is emphasized because hydrogen bromide is prone to condensation if the temperature is too low, for example, less than 20° C., or even in some cases, less than 30° C., resulting in retarded etching rate.

Further, it is noted that due to the property of hydrogen bromide, a source power of at least 800 Watts and a bias power are both needed in order to effectively carried out the present invention HBr/Cl₂ plasma etching.

According to the first preferred embodiment of this invention, the flowrate of HBr is about 0-1200 standard cubic centimeter per minute (sccm), the flowrate of chlorine is about 0-1200 sccm, and the flowrate of oxygen (optional) is about 0-1200 sccm. Introduction of oxygen increases both the etching rates of silicon nitride and silicon oxide.

It is advantageous to use the present invention HBr/Cl₂ plasma etching because the nitride-to-oxide selectivity is increased up to at least 200, and thus the silicon oxide layer 16 is not etched through.

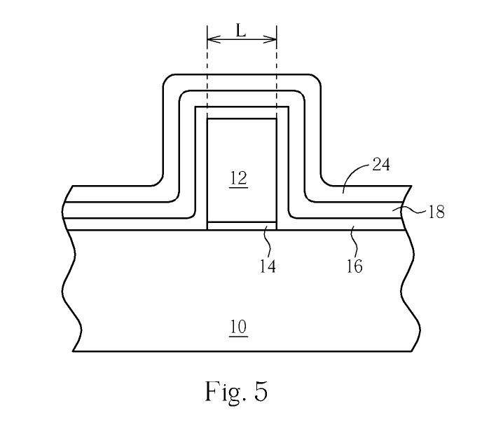

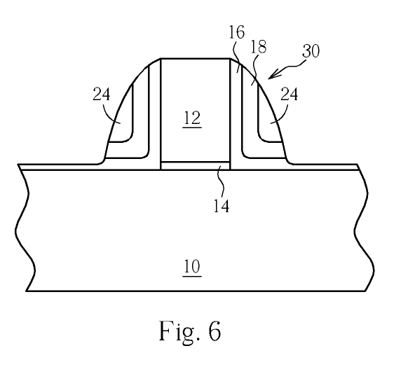

Please refer to FIG. 5 and FIG. 6. FIG. 5 and FIG. 6 are schematic, cross-sectional diagrams illustrating the etching of oxide-nitride-oxide (ONO) spacers utilizing HBr/Cl₂ plasma in accordance with the second preferred embodiment of this invention. As shown in FIG. 5, likewise, a gate 12 having a gate channel length L of about 40-100 nm is formed on the main surface of the semiconductor substrate 10. The formed gate 12 may comprise polysilicon and silicide. A 5-30 angstrom thick gate oxide layer 14 is disposed between the gate 12 and the substrate 10.

Subsequently, conventional CVD processes are performed to deposit a silicon oxide layer 16, a silicon nitride layer 18, and a silicon oxide layer 24 onto the gate 12 and onto the semiconductor substrate 10. The silicon oxide layer 16 covers the top surface and sidewalls of the gate 12. According to this preferred embodiment, the thickness of the silicon oxide layer 16 is about 80-200 angstroms, the thickness of the silicon nitride layer 18 is about 100-500 angstroms, and the thickness of the silicon oxide layer 24 is about 80-500 angstroms.

As shown in FIG. 6, after the CVD deposition of the silicon oxide layer 24, the substrate 10 is placed in an airtight vacuum chamber (not shown) of an etcher tool such as Lam 2300 series etcher tool available from Lam Research Corp. under a chamber pressure maintained at 5-200 mTorr and a chamber temperature of about 70° C. Plasma source gases including hydrogen bromide, chlorine, and, optionally, oxygen are introduced into the vacuum chamber. The HBr/Cl₂ plasma is then ignited by providing the plasma source gas with a source power of no less than 800 Watts and a bias power of about 100-200 Watts. The dielectric layers 16, 18 and 24 are exposed to the HBr/Cl₂ plasma and anisotropically etched to form ONO spacers 30.

According to the second preferred embodiment of this invention, the flowrate of HBr is about 0-1200 standard cubic centimeter per minute (sccm), the flowrate of chlorine is about 0-1200 sccm, and the flowrate of oxygen (optional) is about 0-1200 sccm. Under the above-described conditions, the etching rate of the silicon nitride is about 40-60 angstroms/minute.

Further, it is noted that the present invention HBr/Cl₂ plasma recipe is also suitable for etching polysilicon with very high selectivity to silicon oxide.

In addition to the above-described gate spacer process, the present invention HBr/Cl₂ plasma etching is also suited for other semiconductor processing stages, for example, the front-end contact hole process and the back-end dual damascene interconnection process.

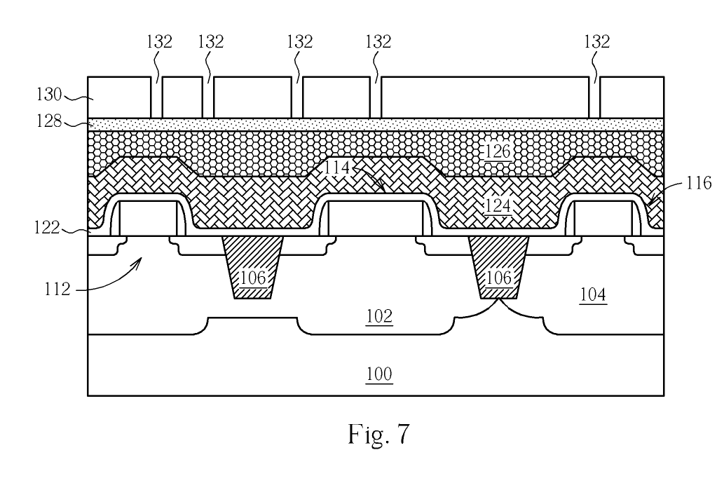

FIGS. 7-10 are schematic, cross-sectional diagrams showing the exemplary process of making contact holes by employing the present invention HBr/Cl₂ plasma etching. As shown in FIG. 7, a semiconductor substrate 100 such as a P type silicon substrate having thereon a P well 102, an N well 104, and shallow trench isolation (STI) regions 106 are provided. An NMOS transistor 112, an NMOS transistor 114, and a PMOS transistor 116 are formed on the semiconductor substrate 100. The STI region 106 is located between the transistors for isolation purpose.

Subsequently, using conventional CVD methods, a contact etch stop layer (CESL) 124 such as a silicon nitride layer is deposited over the NMOS transistor 112, an NMOS transistor 114, and a PMOS transistor 116 and over the semiconductor substrate 100, an un-doped silicon glass (USG) layer 124 is then deposited on the CESL 122, and a PSG dielectric layer 126 is deposited on the USG layer 124. A hard mask 128 such as polysilicon or silicon nitride is then deposited on the PSG dielectric layer 126. Thereafter, a photoresist layer 130 is coated on the hard mask 128. Using conventional lithography methods, openings 132 that define the contact hole pattern are formed in the photoresist layer 130.

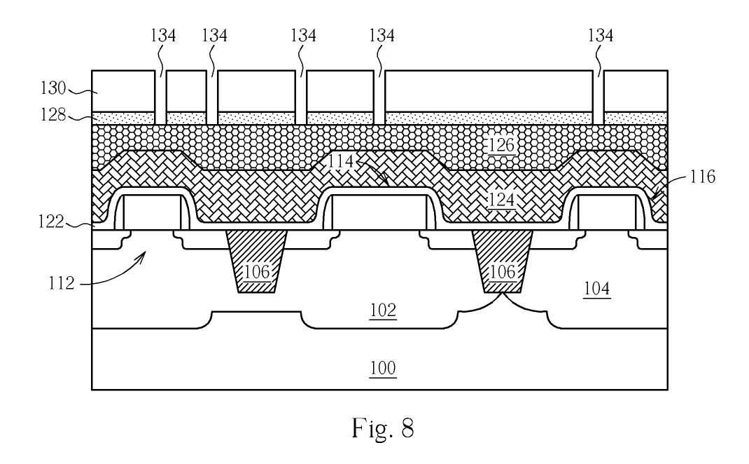

As shown in FIG. 8, using the patterned photoresist layer 130 as an etching hard mask, the exposed hard mask 128 is etched away through the openings 132 to form openings 134 by performing the present invention HBr/Cl₂ plasma etching. The present invention HBr/Cl₂ plasma etching is performed by placing the substrate 100 in an airtight vacuum chamber (not shown) of an etcher tool such as Lam 2300 series etcher tool available from Lam Research Corp. under a chamber pressure maintained at 5-200 mTorr and a chamber temperature of about 70° C., introducing plasma source gases including hydrogen bromide, chlorine, and, optionally, oxygen into the vacuum chamber, and igniting the HBr/Cl₂ plasma by providing the plasma source gas with a source power of no less than 800 Watts and a bias power of about 100-200 Watts. The flowrate of HBr is about 0-1200 sccm, the flowrate of chlorine is about 0-1200 sccm, and the flowrate of oxygen (optional) is about 0-1200 sccm.

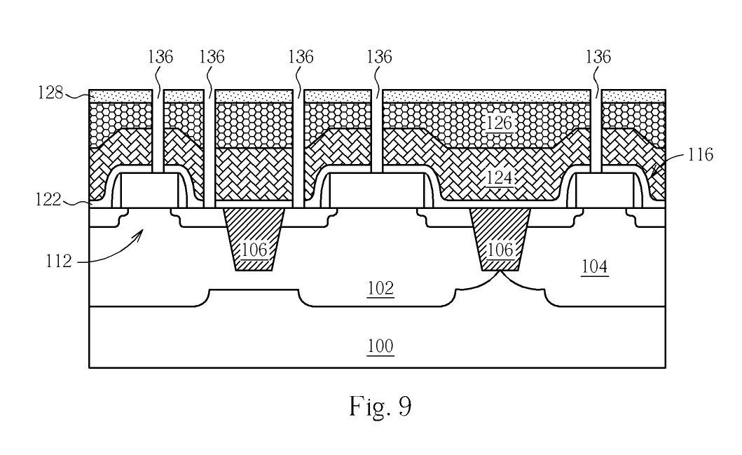

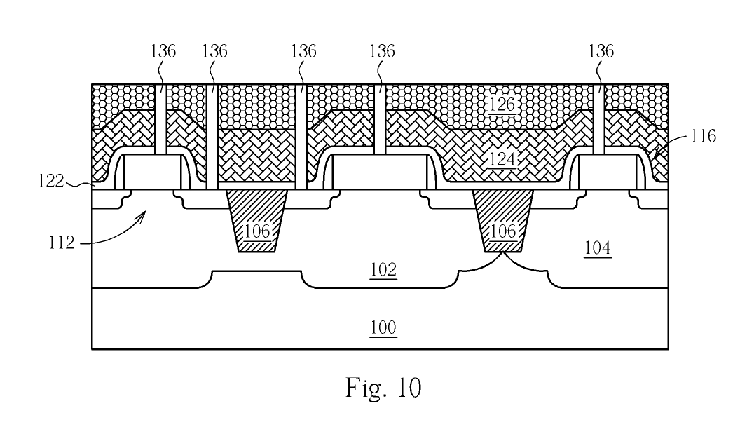

As shown in FIG. 9, subsequently, using the patterned hard mask 128 as an etching mask, the underlying PSG dielectric layer 126, the USG layer 124, and the CESL 122 are anisotropically etched through the openings 134 to form contact holes 136. The PSG dielectric layer 126, the USG layer 124 and CESL 122 can be etched by employing conventional carbon fluoride plasma methods with lower nitride-to-oxide selectivity. Finally, as shown in FIG. 10, the hard mask 128 is removed.

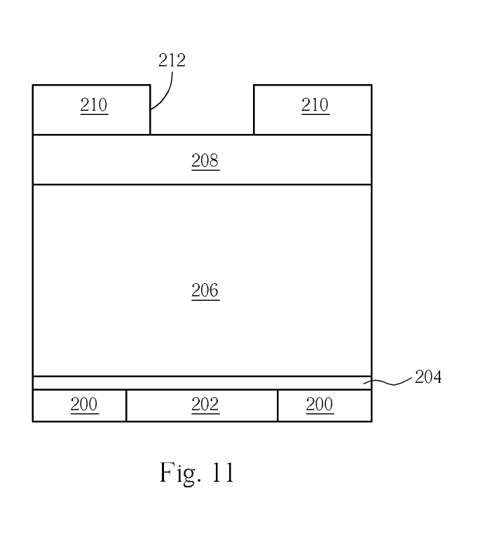

FIGS. 11-15 are schematic, cross-sectional diagrams showing the exemplary process of making a dual damascene structure by employing the present invention HBr/Cl₂ plasma etching. Conventionally, a metal hard mask is necessary in the process of making a dual damascene structure. According to this invention, the metal hard mask is omitted.

As shown in FIG. 11, a lower metal wiring line 202 is formed in the base layer 200 such as a dielectric layer. A silicon nitride cap layer 204 covers the lower metal wiring line 202 and the base layer 200. A low-k dielectric layer 206 such as silicon oxide is formed on the silicon nitride cap layer 204. A silicon nitride hard mask layer 208 is deposited on the low-k dielectric layer 206. A photoresist layer 210 is then coated on the silicon nitride hard mask layer 208. A conventional lithography method is employed to form an opening 212 that exposes and defines the area to be etched into the silicon nitride hard mask layer 208. The opening 212 defines the pattern of the upper metal wiring layer.

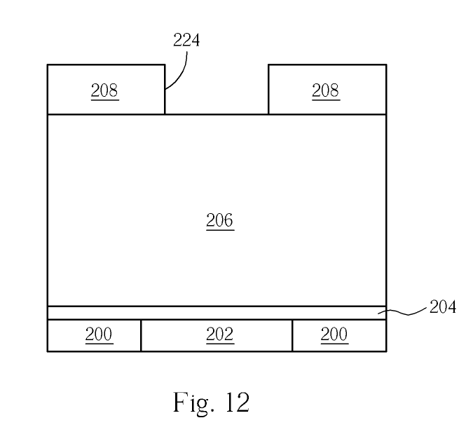

As shown in FIG. 12, using the patterned photoresist layer 210 as an etching hard mask, the exposed silicon nitride hard mask 208 is etched away through the openings 212 to form openings 224 by performing the present invention HBr/Cl₂ plasma etching. The present invention HBr/Cl₂ plasma etching is performed by placing the substrate in an airtight vacuum chamber (not shown) of an etcher tool such as Lam 2300 series etcher tool available from Lam Research Corp. under a chamber pressure maintained at 5-200 mTorr and a chamber temperature of about 70° C., introducing plasma source gases including hydrogen bromide, chlorine, and, optionally, oxygen into the vacuum chamber, and igniting the HBr/Cl₂ plasma by providing the plasma source gas with a source power of no less than 800 Watts and a bias power of about 100-200 Watts. The flowrate of HBr is about 0-1200 sccm, the flowrate of chlorine is about 0-1200 sccm, and the flowrate of oxygen (optional) is about 0-1200 sccm.

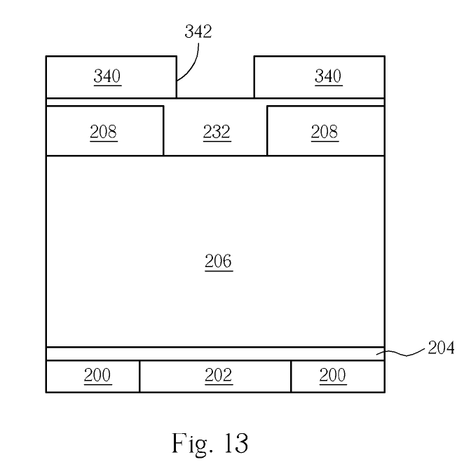

As shown in FIG. 13, after the formation of the openings 224 in the silicon nitride hard mask 208, a dielectric layer 232 is deposited to fill the openings 224 and cover the silicon nitride hard mask 208. A photoresist layer 340 is then formed on the dielectric layer 232. A conventional lithography method is employed to form an opening 342 that exposes and defines the area to be etched into the low-k dielectric layer 206. The opening 342 defines the via pattern which is used to electrically connected the lower metal wiring layer 202 with the upper metal wiring layer.

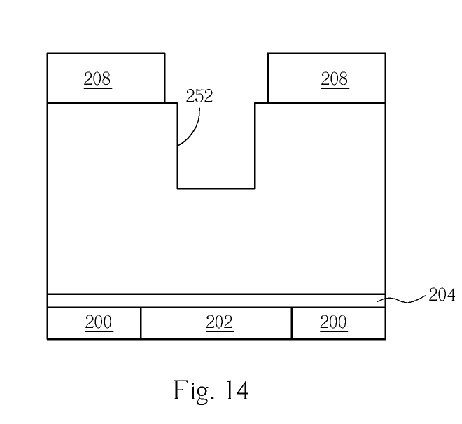

As shown in FIG. 14, using the patterned photoresist layer 340 as an etching hard mask, the exposed dielectric layer 232 and substantially half thickness of the underlying low-k dielectric layer 206 are anisotropically etched away through the openings 342. The photoresist layer 340 and the remaining dielectric layer 232 are removed to form a recess region 252 in the low-k dielectric layer 206.

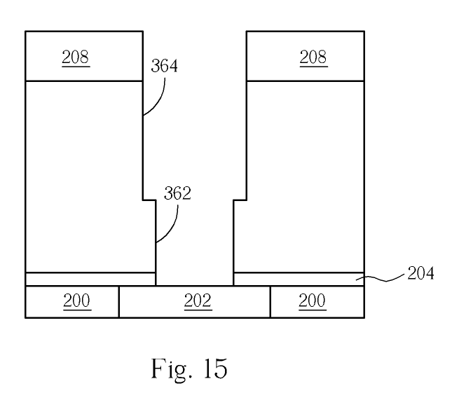

Finally, as shown in FIG. 15, using the silicon nitride hard mask 208 as an etching hard mask, an anisotropic dry etching process is performed to etch the low-k dielectric layer 206 through the opening 224 and through the recess region 252 to form an upper trench 364 and a via hole 362. The via hole exposes a portion of the lower metal wiring layer 202.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a semiconductor device, comprising:
forming a gate on a semiconductor substrate and a gate oxide between said gate and said semiconductor substrate;
depositing a silicon oxide liner layer on said gate and on said semiconductor substrate;
depositing a silicon nitride layer on said silicon oxide liner layer; and
anisotropically etching said silicon nitride layer by employing hydrogen bromide plasma created by using plasma source gas mixture containing hydrogen bromide and chlorine thereby forming spacer on sidewalls of said gate.

2. The method according to claim 1 wherein said hydrogen bromide plasma is produced at a temperature of about 50-150° C., a pressure of 5-200 mTorr, a source power of no less than 800 Watts, and a bias power of about 100-200 Watts.

3. The method according to claim 1 wherein said hydrogen bromide has a flowrate of 0-1200 sccm and said chlorine has a flowrate of 0-1200 sccm.

4. The method according to claim 1 wherein said plasma source gas mixture further contains oxygen.

5. The method according to claim 4 wherein said oxygen has a flowrate of 0-1200 sccm.

6. A method of selectively dry etching a silicon nitride layer over a silicon oxide layer, comprising:
providing a semiconductor substrate having thereon a silicon oxide layer;
depositing a silicon nitride layer on said silicon oxide layer;
forming a photoresist layer on said silicon nitride layer, said photoresist layer having an opening that exposes a portion of said silicon nitride layer; and
using said photoresist layer as an etching hard mask, anisotropically etching said silicon nitride layer through said opening by employing hydrogen bromide plasma created by using plasma source gas mixture containing hydrogen bromide and chlorine until said silicon oxide layer is exposed.

7. The method according to claim 6 wherein said hydrogen bromide plasma is produced at a temperature of about 50-150° C., a pressure of 5-200 mTorr, a source power of no less than 800 Watts, and a bias power of about 100-200 Watts.

8. The method according to claim 6 wherein said hydrogen bromide has a flowrate of 0-1200 sccm and said chlorine has a flowrate of 0-1200 sccm.

9. The method according to claim 6 wherein said plasma source gas mixture further contains oxygen.

10. The method according to claim 9 wherein said oxygen has a flowrate of 0-1200 sccm.
